(19) United States
(12) Patent Application Publication
(10) Pub. No.: US 2011/0021360 A1
(43) Pub. Date: Jan. 27, 2011

(54) Superconductive nanocomposite

(76) Inventors: Ahmed Abdullah S. Al-Ghamdi, Jeddah (SA); El-Sayed El-Badaway H. El-Mossalamy, Jeddah (SA); Farid Mahmoud El-Tantawy, Balgam (SA); Nadia Abdel Aal, AL-Baha (SA)

Correspondence Address: LITMAN LAW OFFICES, LTD., PATENT LAW BUILDING, 8955 CENTER STREET, MANASSAS, VA, 20110, US

(21) Appl. No.: 12/458,782

(22) Filed: Jul. 22, 2009

(51) Int. Cl. H01L 39/02; H01L 39/00; H01P 1/20; H01L 39/24

(52) U.S. Cl. 505/121; 505/100; 505/150; 505/210; 505/160; 505/300; 505/440; 428/221; 374/183; 174/388

(57) ABSTRACT

The superconductive nanocomposite is a composition formed by nanoparticles of a high temperature superconductor blended with a polymer matrix containing natural rubber and polyethylene. The high temperature superconductor is preferably a bismuth-based superconductor (BSCCO) having a particle size of about 21 nm, but may be any other high temperature or Type II ceramic, metal oxide superconductor. The superconductor nanoparticles comprise about 15% of the weight of natural rubber in the composition. The polyethylene is preferably low density polyethylene and may comprise between 0% up to about 40% of the weight of natural rubber in the composition. The nanocomposite may be prepared by blending the components and roll milling the rubber. Depending upon the percentage of polyethylene present in the matrix, the nanocomposite has useful applications as a double thermistor (both positive and negative coefficients of electrical resistivity), for antistatic charge dissipation, and for electromagnetic shielding in the microwave region.

### BACKGROUND OF THE INVENTION

1. Field of the Invention

The present invention relates to superconductors, and particularly to a superconductive nanocomposite formed from nanoparticles of a high temperature superconductor disposed in a natural rubber-polyethylene polymer matrix.

2. Description of the Related Art

Superconductors exhibit the unique property of having zero electrical resistance below a certain critical temperature, usually designated as T_{c}. Type I superconductors include tin, aluminum, certain alloys, and other materials that have a critical temperature of about 30 degrees Kelvin. The superconductive phenomenon exhibited by such materials can be explained by quantum mechanical theory.

More recently, it has been found that certain ceramic materials, known as Type II superconductors, also exhibit superconductive behavior, but have higher critical temperatures. Some of these Type II superconductors have critical temperatures above 90 degrees Kelvin, which potentially expands possible applications for superconductors, since their critical temperature is above the boiling point of liquid nitrogen (about 77 degrees Kelvin), making them easier to work with. The superconductivity of Type II superconductors has not been fully explained on a theoretical basis, since they exhibit magnetic effects that are somewhat different than Type I superconductors.

One such high temperature superconductor is ceramic oxide material containing bismuth, lead strontium, calcium, and copper (BSCCO), sometimes referred to as a bismuth oxide or cuprate oxide superconductor. However, like other metal oxide superconductors, the range of applications for bismuth oxide superconductors has been limited, since the oxide is brittle and difficult to draw as a wire. Consequently, there is a need for a matrix for high temperature, metal oxide superconductors, and particularly for bismuth-based superconductors.

Thus, a superconductive nanocomposite solving the aforementioned problems is desired.

### SUMMARY OF THE INVENTION

The superconductive nanocomposite is a composition formed by nanoparticles of a high temperature superconductor blended with a polymer matrix containing natural rubber and polyethylene. The high temperature superconductor is preferably a bismuth-based superconductor (BSCCO) having a particle size of about 21 nm, but may be any other high temperature or Type II ceramic, metal oxide superconductor. The superconductor nanoparticles comprise about 15% of the about 15% of the weight of natural rubber in the composition. The polyethylene is preferably low density polyethylene and may comprise between 0% up to about 40% of the weight of natural rubber in the composition. The nanocomposite may be prepared by blending the components and roll milling the rubber. Depending upon the percentage of polyethylene present in the matrix, the nanocomposite has useful applications as a double thermistor (both positive and negative coefficients of electrical resistivity), for antistatic charge dissipation, and for electromagnetic shielding in the microwave region.

These and other features of the present invention will become readily apparent upon further review of the following specification and drawings.

### BRIEF DESCRIPTION OF THE DRAWINGS

FIG. 1A is a scanning electron micrograph (SEM) of a conductive elastomer composition according to the present invention with 0% polyethylene.

FIG. 1B is a scanning electron micrograph (SEM) of a conductive elastomer composition according to the present invention with 10% polyethylene.

FIG. 1C is a scanning electron micrograph (SEM) of a conductive elastomer composition according to the present invention with 20% polyethylene.

FIG. 1D is a scanning electron micrograph (SEM) of a conductive elastomer composition according to the present invention with 30% polyethylene.

FIG. 2 is a chart showing crosslinking density, percent bound rubber, and Mooney viscosity as a function of percent polyethylene content of a conductive elastomer composition according to the present invention.

FIG. 3 is a chart showing tensile strength, hardness, and elongation at break as a function of percent polyethylene content of a conductive elastomer composition according to the present invention.

FIG. 4 is a chart showing resistivity, mobility, and charge density as a function of percent polyethylene content of a conductive elastomer composition according to the present invention.

FIG. 5 is a chart showing resistivity as a function of temperature of a conductive elastomer composition according to the present invention.

FIG. 6 is a chart showing energy and intensity as a function of percent polyethylene content of a conductive elastomer composition according to the present invention.

FIG. 7 is a chart showing static energy and RC decay time as a function of percent polyethylene content of a conductive elastomer composition according to the present invention.

FIG. 8 is a chart showing voltage as a function of time for a conductive elastomer composition according to the present invention.

FIG. 9 is a chart showing conductivity, skin depth, and EMI as a function of percent polyethylene content of a conductive elastomer composition according to the present invention.

FIG. 10 is a chart showing EMI as a function of frequency for a conductive elastomer composition according to the present invention.

FIG. 11 is a chart showing theoretical EMI as a function of frequency for a conductive elastomer composition according to the present invention.

Similar reference characters denote corresponding features consistently throughout the attached drawings.

### DETAILED DESCRIPTION OF THE PREFERRED EMBODIMENTS

The superconductive nanocomposite is a composition formed by nanoparticles of a high temperature superconductor blended with a polymer matrix containing natural rubber and polyethylene. The high temperature superconductor is preferably a bismuth-based superconductor (BSCCO) having a particle size of about 21 nm, but may be any other high temperature or Type II ceramic, metal oxide superconductor. The superconductor nanoparticles comprise about 15% of the weight of natural rubber in the composition. The polyethylene is preferably low density polyethylene and may comprise between 0% up to about 40% of the weight of natural rubber in the composition. The nanocomposite may be prepared by blending the components and roll milling the rubber. Depending upon the percentage of polyethylene present in the matrix, the nanocomposite has useful applications as a double thermistor (both positive and negative coefficients of electrical resistivity), for antistatic charge dissipation, and for electromagnetic shielding in the microwave region.

The superconductive nanocomposite is best understood by reference to the following example.

### Example

Samples of nominal compositions Bi_{1.93}PbO_{0.33}Sr₂Ca_{2.5}Cu_{3.5}O_{y}, were prepared by the acetate-tartrate gel precursor technique. Stoichiometric amounts of analytical grade Bi₂O₃, PbO, Ca(NO₃)₃, Sr(CH₃COO)₂ and Cu(CH₃COO)₂. H₂O were used as starting materials. First, in the sol-gel process, an appropriate amount of the Bi₂O₃ and PbO was dissolved in 0.2 M H₂COOH. After stirring for 2 hours at 90° C., a clear solution was obtained. Next, copper acetate, calcium nitrate, and strontium nitrate were all dissolved in small amounts of distilled water and were added to the bismuth acetate solution with adequate intermediate stirring. Finally, after concentrating for 20 hours at 90° C. in an open beaker, the acetate/tartrate solutions turned into blue or slightly greenish gels. The obtained Bi_{1.93}PbO_{0.33}Sr₂Ca_{2.5}Cu_{3.5}O_{y}, gels were dried in air at 100° C. for 1 day. The mixtures so obtained were pressed into 20 mm disk-shaped pellets at a pressure of P=200 KN/m² and then calcined at 820° C. for 3 hours in air. The product was then subjected to grinding, re-pelletized, and then sintered at 855° C. for 20 hours in air. Bismuth-based powder with a particle size of about 21 nm was received from the above method.

A blend of natural rubber (NR) and low density polyethylene (PE) was used as a polymer matrix. Bismuth-based superconductor ceramic (labeled as BSCCO) was used as conductive filler and was prepared by sol-gel technique to obtain nanoparticles, as reported above. Other ingredients, such as commercial grades of zinc oxide (ZnO); stearic acid (SA); zinc-diethyldithiocarbamate (ZDC), 1,2-mercaptobenzothiazole (MBT), and sulfur (S) were used without further purification. A typical formulation of NR/PE blend compound is presented in Table I.

TABLE I
Formulations of the mixes

| | Sample name | | | | |
|---|---|---|---|---|---|
| Ingredients | PE0 | PE10 | PE20 | PE30 | PE40 |
| NR | 100 | 90 | 80 | 70 | 60 |
| PE | 0 | 10 | 20 | 30 | 40 |
| BSCCO | 15 | 15 | 15 | 15 | 15 |
| ZnO | 6 | 6 | 6 | 6 | 6 |
| SA | 1 | 1 | 1 | 1 | 1 |
| ZDC | 1 | 1 | 1 | 1 | 1 |
| MBT | 1 | 1 | 1 | 1 | 1 |
| S | 1.5 | 1.5 | 1.5 | 1.5 | 1.5 |

The mixing was accomplished in an open two-roll mill under identical conditions of time, temperature and nip gap, with the same sequence of mixing of all compounding ingredients to avoid the effect of processing on physical properties. The vulcanization process of the polymer compounds was carried out in an electrically heated hydraulic press using a special homemade mold at a temperature of 1600° C. and under pressure of 300 KN/m² for 30 minutes. Then, the blends were cured under hot, uniaxial pressure of 200 KN/m² at 150° C. for 2 hours.

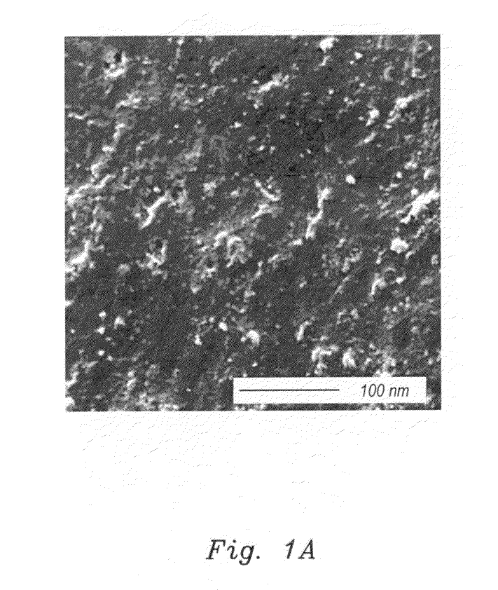

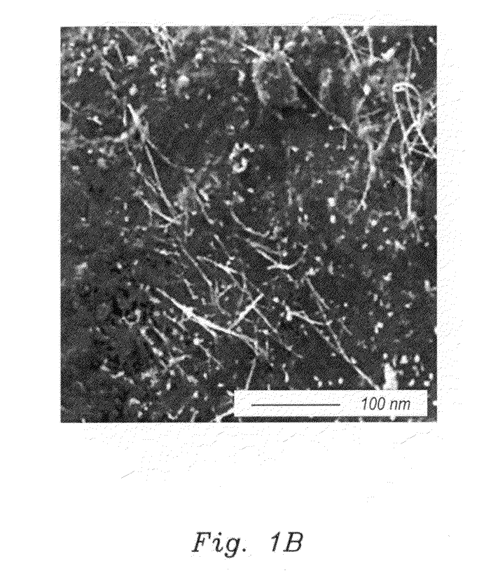

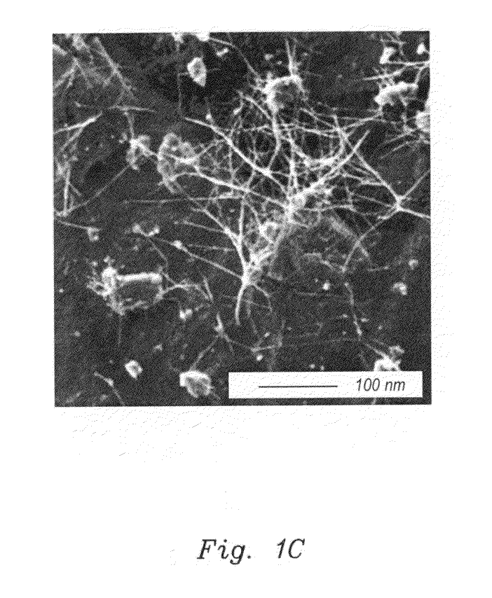

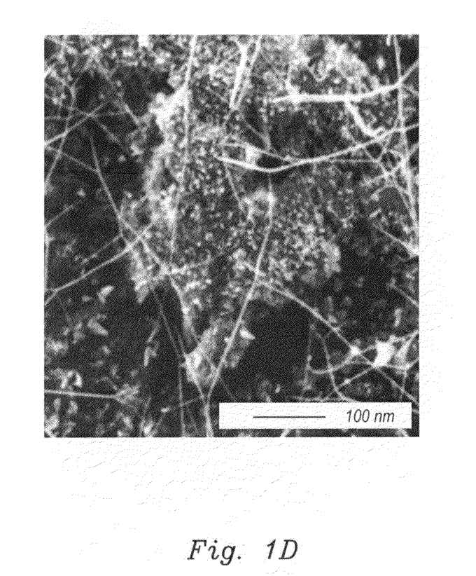

The morphology development in the blends with increasing PE loading may be followed from the SEM images shown in FIGS. 1A through 1D for the various blend samples containing 0 wt %, 10 wt %, 20 wt %, 30 wt % and 40 wt % of PE, respectively. It is apparent from the SEM micrograph in FIG. 1A that the BSCCO particles form a highly entangled, interconnected structure in the NR matrix. Furthermore, the BSCCO particles appear to be uniformly distributed in the entire volume of the NR matrix. The SEM image in FIG. 1B for the PE10 sample shows that the fine fibers of PE could be observed as a mesh-like, continuous connection structure linking the NR domains. This leads to the increase of interfacial adhesion among filler and blend, and also to an increase in bonding adhesion, i.e., the crosslinking density of the blends, which contributes to the improved physical properties of the blends. One may conclude that at PE≦10 wt %, the PE builds a conducting infinite cluster over the entire blend. On the other hand, the SEM images in FIGS. 1C and 1D, i.e., PE20 and PE30 samples, respectively, it is thought that with PE>10 wt %, the PE formed a fabric-like structure in the elastomer matrix and contributed to the formation of a shielding screen (i.e., an insulating mesh) to prevent the transport of charge carriers into the blend, and thereby the resistivity of the blends increases, as discussed below.

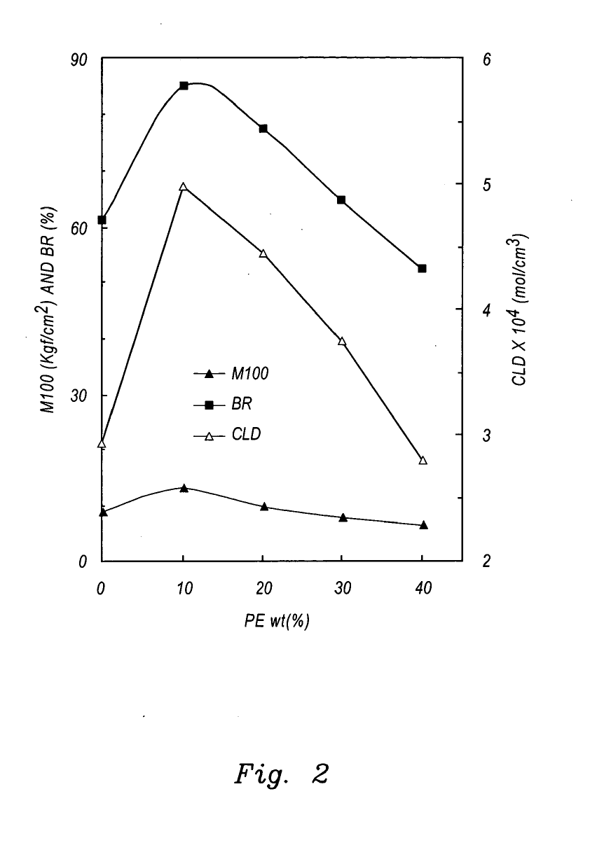

To gain more insight on the above assumption, the crosslinking density CLD, bound rubber BR, and Mooney viscosity M₁₀₀ were evaluated, and the results are presented in FIG. 2. It is clear that the CLD, BR and M₁₀₀ increase with increasing PE (polyethylene) content up to 10 wt %, and then decrease with increasing PE content in the blend. The increase of CLD within the matrix leads to a decrease in the volume fraction of unbound (free) rubber in the matrix, and at the same time, to an increase in the interface interactions between BSCCO particles and elastomer matrix. The slight increase of BR with further addition of PE up to about 10 wt % is due to improvement of filler dispersion in the elastomer matrix, which tends to increase the formation of BR.

Higher M₁₀₀ values are observed by increasing the fraction of PE up to about 10 wt %. One possible explanation for the increase of the Mooney viscosity can be ascribed to facile mobility carriers and polymer-polymer interactions, which induces rigidity of the polymer chains. The increase of M₁₀₀ for sample PE10 is a strong clue that PE≦10 wt %, enhances crosslinking efficiency and restricts polymer chain mobility. Therefore, rigidity of the polymer chains increases in the blend system.

The mechanical properties in filled rubber vulcanates can be explained in view of the bound rubber concept, which is a result of the interaction between elastomer and filler. Bound rubber is formed in filled elastomer compounds by physical absorption, chemisorption, and mechanical interaction, and depends on various factors, such as polarity, the microstructure of the polymer, structure, surface activity of the filler, and interface adhesion between filler and matrix.

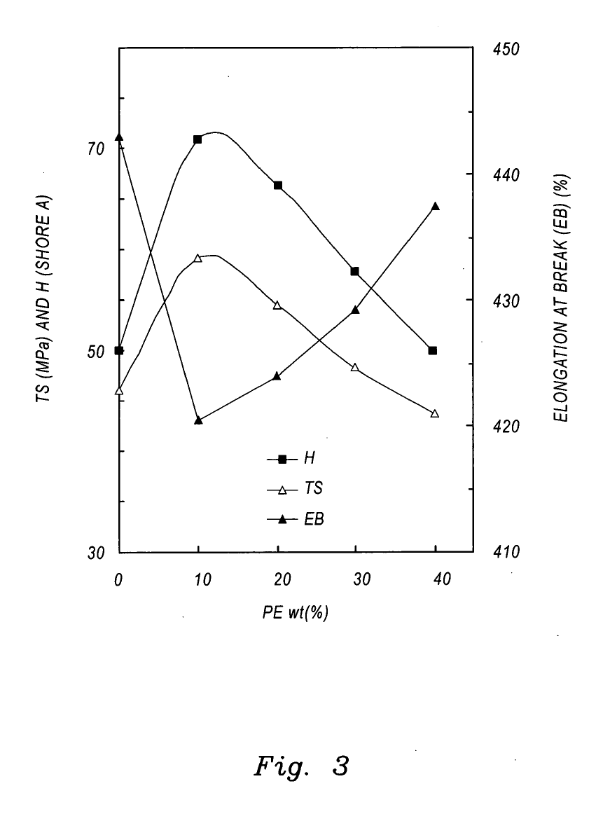

Tensile strength TS, hardness Hand elongation at break EB as a function of PE content of the blend is illustrated in FIG. 3. It is clear that the tensile strength increases to a maximum value at 10 wt % PE and then decreases. This can be explained by the increase in the bound elastomer and the degree of crystallinity of the elastomer matrix caused by the addition of PE up to 10 wt %. Also, the increase of tensile strength may be attributed to the strong filler-blend interphase interaction and good BSCCO particle dispersion into the blend, as confirmed by SEM in FIG. 1A.

Tensile strength of the sample decreases with increasing the PE content to more than 10 wt % in the blend. This behavior may be explained by the fact that segregation along the polymer-filler interface is due to weak adhesion between filler and matrix when increasing the PE content to more than 10 wt %. In addition, when PE>10 wt %, the intermolecular forces within the rubber matrix decrease, which leads to more flaws in the rubber matrix, and to lower crosslinking density and bound elastomer. It is worthy to note that the PE10 sample gave a higher hardness compared to other samples, which indicates that there is some sort of interaction between polymer and filler. The highest hardness of the PE10 sample is ascribed to the complete compatibility of polyethylene with the NR matrix so that the polymer blend molecules are very compact. This makes the dispersion of PE in the NR matrix better, so that PE works as a compatibility agent and/or wet agent to give the polymer blend. This is reflected in the chain connectivity and interfacial adhesion increase in the blends with increasing PE content up to 10 wt %, as confirmed above.

In FIG. 3, elongation at break decreases with increasing PE content up to 10 wt %. This is attributed to the increase in crosslinking density and bound elastomer of the blend. In addition, the decrease of elongation at break with increasing PE content to more than 10 wt % is ascribed to the bonding adhesion between elastomer and filler. With increasing PE content to more than 10 wt %, the elongation at break increases. This is attributed to weak interface adhesion between filler and matrix. Our results also lead to the conclusion that the improved mechanical properties can be explained by increased interactions at the phase boundaries upon the incorporating PE≦10 wt %, which play an influential role in causing compatibility at a molecular level.

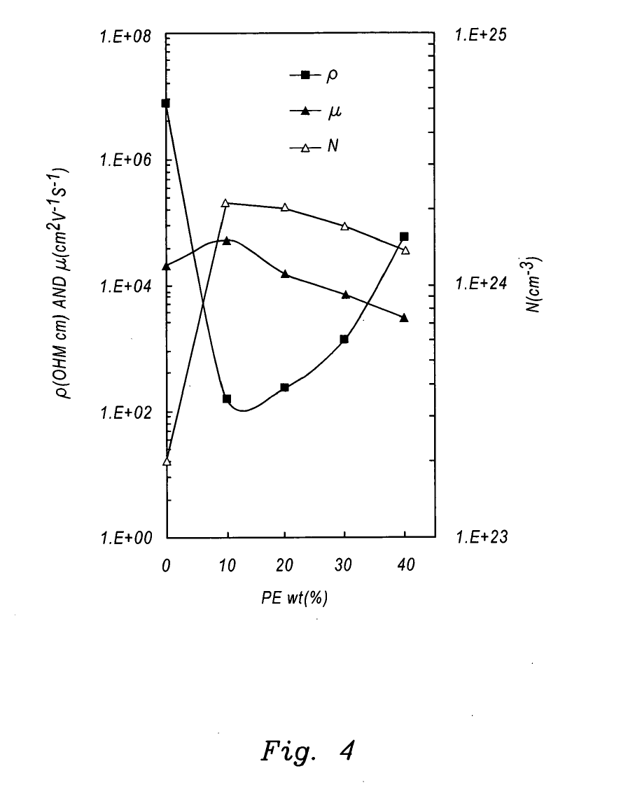

The variations at room temperature of bulk electrical resistivity (ρ=R·(A/l) where ρ is resistivity in Ω-cm, R is resistance in ohms, A is cross-sectional area in cm², and l is length in cm) of the blend samples with PE loading ranging from 0 to 40 wt % is shown in FIG. 4. Electrical resistivity measurements revealed that enhanced conductivity of the blends is strongly related to the blend morphology. One interesting finding is that the room-temperature resistivity value of the sample decreases with an increase in the content of PE up to 10 wt %, after which a drastic increase is observed. The PE10 blend has lower resistivity than the other blends with the same BSCCO content. The decrease in resistivity up to 10 wt % PE is attributed to the PE acting as an ionic species, which leads to an increase of charge carrier mobility (μ in cm²V⁻¹s⁻¹) in the blends, whereby the resistivity decreases. This result is consistent with the SEM observation before in FIGS. 1A and 1B.

As the PE content increased to 10 wt %, more PE-containing liquid phases had formed, i.e., built barriers to decrease the transport or hop of charge carriers by tunneling, which contributes to a higher resistivity. One may be therefore inclined to conclude that PE content up to 10 wt % is directly involved in forming the conducting network. Again, to confirm the above facts, charge carrier mobility μ and number of charges per volume (N per cubic centimeter) as a function of PE content has been measured, and the results are also presented in FIG. 4. The charge carriers are believed to be transported between the domains by a tunneling mechanism.

In FIG. 4, clearly both the number of charges and the charge carrier mobility increase with increasing PE up to 10 wt %, and then decrease with increasing PE loading level. This supports the above idea that PE less than 10 wt % improves the interface adhesion and connectivity among conductive paths. It has been postulated that PE content up to about 10 wt % decorates the connecting paths of the blend network, and, hence, such high charge carriers mobility and number of particles values. On the other hand, with increasing PE to more than 10 wt %, the PE coats the conductive paths and maybe destroys the conductive filaments in the blends, which leads to increase of resistivity, as confirmed by SEM in FIGS. 1A through 1D.

Some conducting composites or blends show a sharp resistivity increase and/or decrease at relatively high temperature, which reflects both positive and negative temperature coefficients of resistivity (PTCR and NTCR). Materials that exhibit both PTCR and NTCR phenomena are said to exhibit a double thermistor effect. Because of a sharp increase or decrease in electrical resistivity, the PTCR and NTCR materials have a wide range of technological applications, such as self-regulating heaters, current limiters, overcurrent protectors, and resettable fuses.

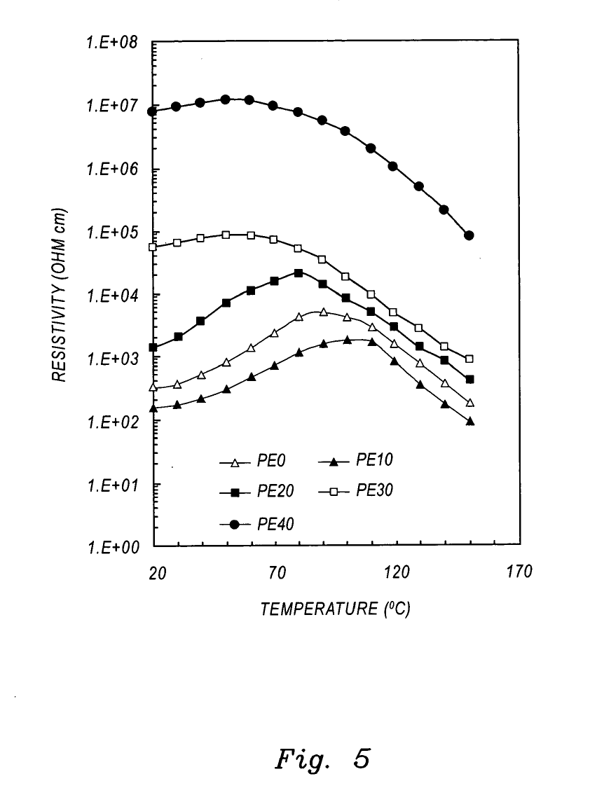

FIG. 5 shows the temperature dependence of the resistivity of the various NR/PE/BSCCO blends. The results of studies of resistivity-temperature dependence for a set of five samples with the same BSCCO content show the increase in resistivity is nearly linear, which suggests the blends have a semiconducting character. This implies that the resistivity is controlled by tunneling or hopping of charges between BSCCO particles through interlayers of a non-conducting elastomer matrix. With increasing temperature, the resistivity increase demonstrates a positive temperature coefficient of resistivity (PTCR) thermistor effect up to a certain temperature, namely, the percolation temperature, and then decreasing resistivity demonstrates a negative temperature coefficient of resistivity (NTCR) thermistor effect. It is interesting to note that the combination of PTCR and NTCR effects (namely, double thermistors) appeared in all blends.

Starting from the laboratory room temperature, the number of BSCCO contacts only gradually diminished and, as a result, a slight increase in resistivity occurred. With increasing temperature, the resistivity rapidly increases. This behavior is due to thermal expansion of the matrix, which causes an increase in the interatomic distances between BSCCO particles and their disconnection. In contrast, however, at the percolation temperature, interruption of the last conductive paths through a sample caused a sudden decrease in resistivity (i.e., the NTCR effect appears). At the percolation temperature, as the particles in the blend are fully separated, the semiconducting character of the blend prevails, and a slight decrease in resistivity with temperature is controlled by charge transport between BSCCO particles through non-conducting elastomer barriers. In addition we believe that the NTCR effect is due to flow of elastomer chains at high temperature.

It is interesting to mention that with decreasing PE content in the blends, the percolation temperature shifts to higher values, and a drop in resistivity is observed. This indicates that the inclusion of PE up to 10 wt % improves the thermal stability and the skeletal molecular structure of the blend.

However, PTCR thermistors can be used as thermal sensors. Therefore, high resistance jumping and temperature coefficient of resistance are necessary for high sensitivity of this kind of sensor for practical use.

It is clear that PTCR intensity increases with increasing PE content up to 10 wt %, then decreases. The improvement in the PTCR intensity effect up to 10 wt % PE can be attributed to an increase in surface acceptor state with the increasing PE content. However, further addition of PE led to a weaker PTCR intensity effect due to the poor quality of grain boundaries arising from the occurrence of more PE-containing liquid phases during vulcanization.

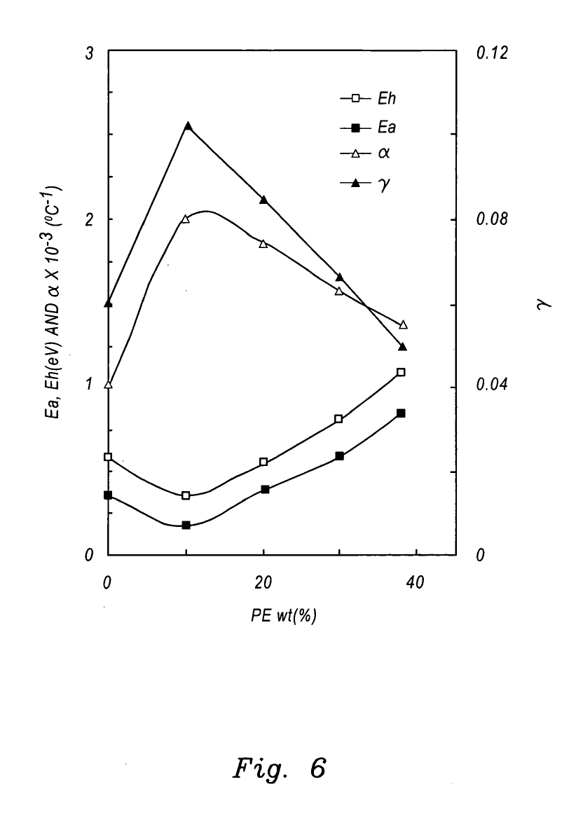

In FIG. 6, the value of the temperature coefficient of resistivity increases with increasing PE content up to 10 wt %, after which decreases. This is ascribed to enhanced crosslinking density and thermal stability of the blend with the inclusion of PE up to 10 wt %, as confirmed above.

Static charge is immovable, and so the generated static charges localized on the surface of the materials cannot be removed. In case of conducting materials, the charges may conduct to some place else and leak to the air, thereby creating a serious static problem. In some extreme cases, a sufficient amount of static charges may generate sparks and cause a fire explosion. For antistatic applications, surfaces with a resistivity of 103-108 Ohm-cm are needed.

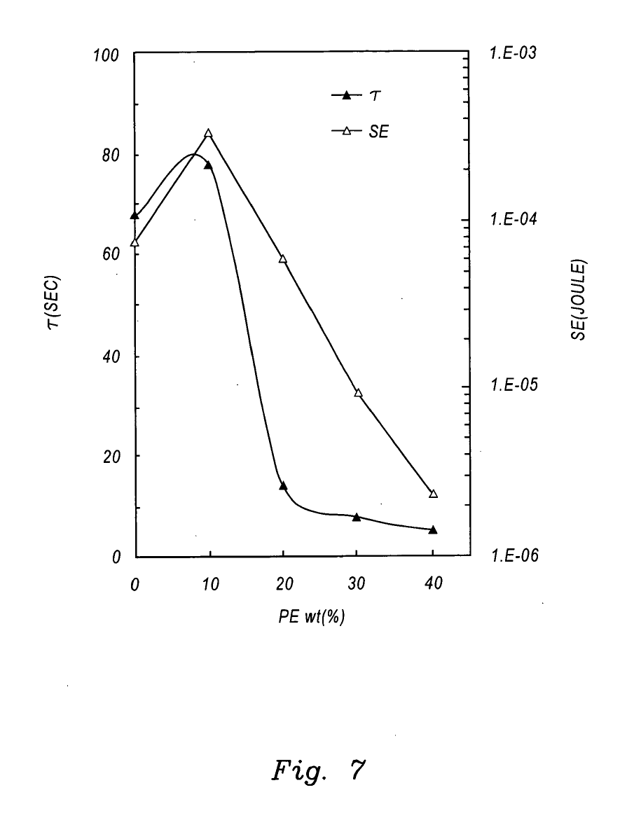

Another interesting aspect of this work is the influence of PE content on static energy (SE) of the blend, as shown in FIG. 7. Examination of FIG. 7 indicates that the values of SE increase with PE≦10 wt %, and then the values decrease. This implies that a conducting network domain is formed on increasing the PE content up to 10 wt % in the blend, which leads to a weaker SE value for the blend. The inventors determined that PE less than wt % gives rise to large SE. This indicates that the values of SE for the PE0 and the PE10 sample are quite acceptable for electromagnetic wave shielding applications. On the other hand, the values of SE for higher loading of the blend, i.e., the PE20, PE30 and PE40 samples are quite acceptable for antistatic charge dissipation applications.

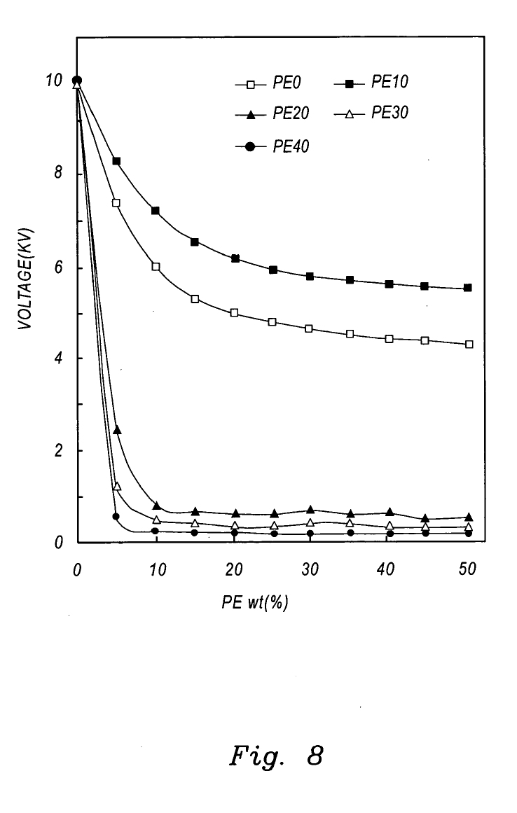

The discharge voltage of the blends as a function of time is plotted in FIG. 8. It is seen that the voltage decreases with time, and then the voltage levels off with further increasing time at levels that depend on the PE content. It is clear that the value of the characteristic exponential decay time constant increases-up to PE 10 wt %, and then decreases with increasing the PE content to more than 10 wt %. It is interesting to mention that the value of the characteristic exponential decay time constant for the PE20, the PE30, and the PE40 sample is less than 10 seconds. Therefore, we recommend using the blends having high PE loading as antistatic charge dissipation or antistatic protection devices.

Electromagnetic interference (EMI) is one of the major factors for malfunction of electronic and electrical equipment. To control (EMI), the housing cabinet of electronic equipment is provided with a conductive shield made up of either metallic enclosures or carbon composites. The effectiveness of such shields is essentially a function of surface resistivity. Shielding effectiveness is described as the attenuation of an electromagnetic wave produced by its passage through a shield and is measured as the ratio of the shield strength before and after attenuation.

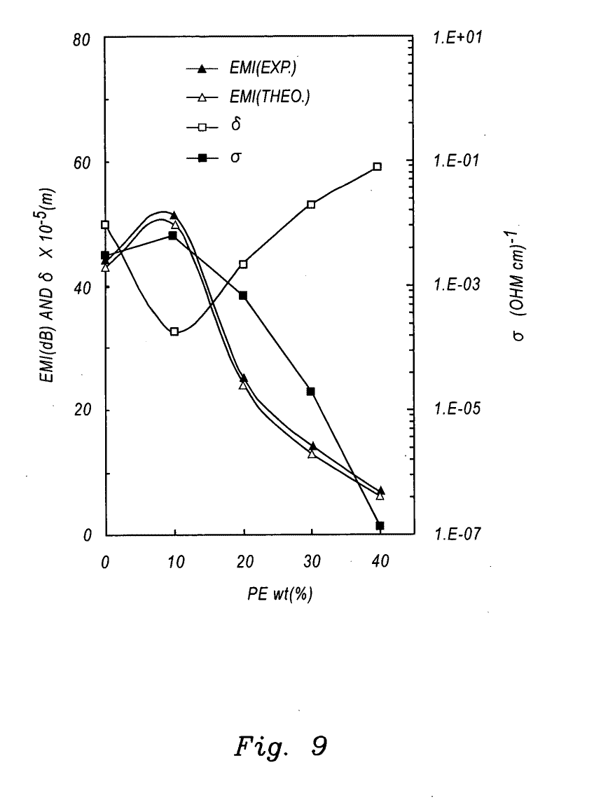

The relationship between EMI and conductivity as a function of PE content is plotted in FIG. 9. The figure reveals that on using PE≦10 wt %, a shielding effectiveness of the order of 44-55 dB is obtained. From FIG. 9, we can also find that the PE40 sample has low EMI because of its poor conductivity. This can be explained as follows. As the PE content increases, the density of isolated conducting domains increases, as seen in the SEM images of FIGS. 1A, 1B, 1C, and 1D, which contributes to weaker interfacial polarization of electromagnetic waves and smaller electromagnetic energy loss. It is observed that the blend has a large amount of isolated conducting domains of PE, which leads to interfacial polarization of electromagnetic waves. However, for most industrial applications, a shielding effectiveness of 30 dB is a useful attenuation value because it will prevent 99.9% of electromagnetic interference. With PE loading increasing from PE0 to PE10, volume conductivity increases sharply, and EMI obviously also increases. This suggests that reflection dominates the shielding mechanism. As the conductivity increases, electromagnetic impedance of the composite becomes smaller and smaller. The level of impedance mismatch to the air becomes larger and larger. Therefore, reflection loss of the electromagnetic wave is strengthened, and EMI increases. In addition, the EMI of the blends depends on resistance loss, and interfacial polarization loss as well. Also, it is seen that the skin depth decreases with increasing conductivity, i.e., for samples PE0 and PE10, and then increases.

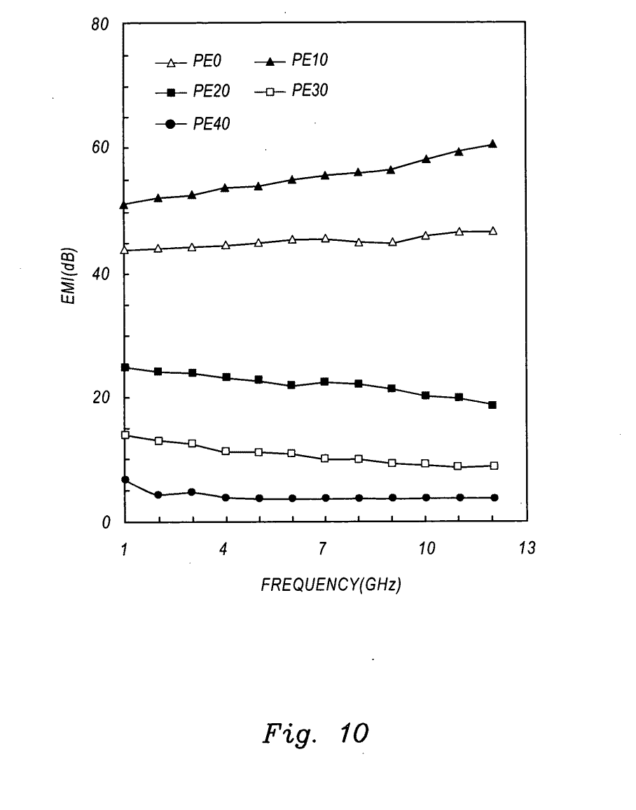

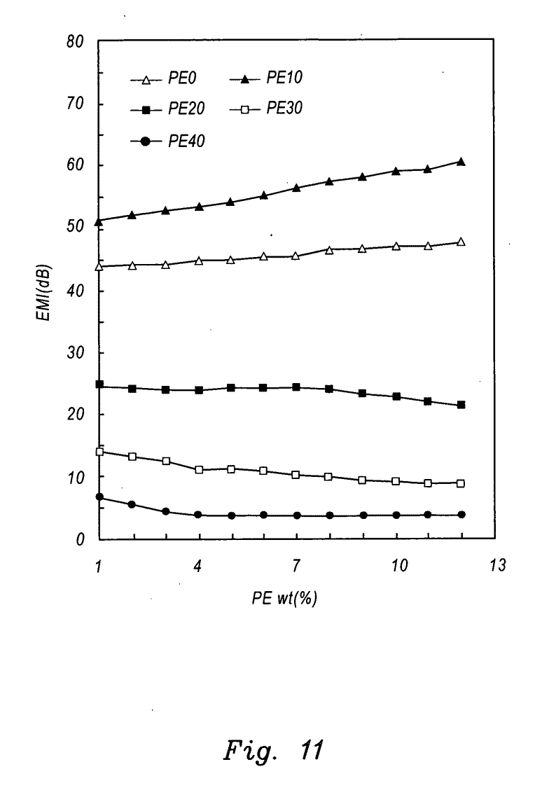

The measured and calculated values of EMI as a function of frequency are plotted in FIGS. 10 and 11, respectively. For all of the blends, the experimental EMI agrees well with the calculated theoretical value for the studied frequency range. Despite some scatterings in the data with respect to frequency, it is apparent that the EMIs of the five samples are similar to each other. The EMI was the highest for the PE10 sample, which had the smallest sample electrical resistivity among all the samples. The addition of PE of more than 10 wt % to NR diminishes the shielding effectiveness from 6 dB to 36 dB. This means that the PE hinders direct contact between the conductive filaments and the particles in the blend. The study revealed that conducting blends show a shielding effectiveness of 44 dB to 60 dB in the microwave range of 8-12 GHz. This makes the superconductive nanocomposite useful for EMI shielding devices and compact EMI suppression filters.

It is to be understood that the present invention is not limited to the embodiments described above, but encompasses any and all embodiments within the scope of the following claims.

We claim:

1. A superconductive nanocomposite, comprising nanoparticles of a high temperature superconductor dispersed in a matrix of natural rubber blended with polyethylene up to 40 wt % of the natural rubber.

2. The superconductive nanocomposite according to claim 1, wherein the high temperature superconductor comprises a ceramic bismuth oxide superconductor.

3. The superconductive nanocomposite according to claim 1, wherein the high temperature superconductor comprises a ceramic oxide containing bismuth, lead strontium, calcium, and copper (BSCCO).

4. The superconductive nanocomposite according to claim 1, wherein the high temperature superconductor comprises a ceramic oxide having the general formula Bi_{1.93}PbO_{0.33}Sr₂Ca_{2.5}Cu_{3.5}O_{y}.

5. The superconductive nanocomposite according to claim 1, wherein the matrix comprises a blend of natural rubber and polyethylene up to 10 wt % of the natural rubber.

6. An electromagnetic shielding device comprising the superconductive nanocomposite of claim 5.

7. An EMI suppression filter for microwave electronic devices, the filter comprising the superconductive nanocomposite of claim 1.

8. A thermistor comprising the superconductive nanocomposite of claim 1.

9. A double thermistor comprising the superconductive nanocomposite of claim 1.

10. The superconductive nanocomposite according to claim 1, wherein the nanoparticles have a size of about 21 nm.

11. A process of making a superconductive nanocomposite, comprising the steps of:
blending nanoparticles of a high temperature superconductor with natural rubber and polyethylene up to 40 wt % of the natural rubber; and
roll milling the blend.

12. The process of making a superconductive nanocomposite according to claim 10, wherein the high temperature superconductor comprises a bismuth oxide superconductor.

13. The process of making a superconductive nanocomposite according to claim 10, further comprising the step of vulcanizing the blend after the roll milling step.

14. The process of making a superconductive nanocomposite according to claim 13, further comprising the step of curing the blend under hot, uniaxial pressure of 200 KN/m² at 150° C. for 2 hours after the vulcanizing step.

15. The process of making a superconductive nanocomposite according to claim 10, wherein the high temperature superconductor comprises a bismuth oxide superconductor having the general formula Bi_{1.93}PbO_{0.33}Sr₂Ca_{2.5}Cu_{3.5}O_{y}, the process further comprising the step of forming the superconductor by a sol-gel process.

16. A superconductive nanocomposite, comprising nanoparticles of a high temperature superconductor having the general formula Bi_{1.93}PbO_{0.33}Sr₂Ca_{2.5}Cu_{3.5}O_{y} dispersed in a matrix of natural rubber blended with polyethylene between 0 wt % up to about 40 wt % of the natural rubber, the nanoparticles comprising about 15% of the weight of natural rubber in the blend.

17. The superconductive nanocomposite according to claim 16, wherein the matrix comprises a blend of natural rubber and polyethylene up to 10 wt % of the natural rubber.

18. An electromagnetic shielding device comprising the superconductive nanocomposite of claim 17.

19. An EMI suppression filter for microwave electronic devices, the filter comprising the superconductive nanocomposite of claim 16.

20. A thermistor comprising the superconductive nanocomposite of claim 16.
